(19) United States
(12) Patent Application Publication
(10) Pub. No.: US 2009/0102048 A1
(43) Pub. Date: Apr. 23, 2009

(54) ELECTRONIC DEVICE AND MANUFACTURING METHOD THEREOF

(76) Inventor: Eiji Hori, Tokyo (JP)

Correspondence Address: NEC CORPORATION OF AMERICA, 6535 N. STATE HWY 161, IRVING, TX, 75039, US

(21) Appl. No.: 12/256,153

(22) Filed: Oct. 22, 2008

(30) Foreign Application Priority Data
Oct. 23, 2007 (JP) 2007-275318

(51) Int. Cl. H01L 23/488; H01L 21/60

(52) U.S. Cl. 257/737; 438/106; 257/E21.511; 257/E23.023

(57) ABSTRACT

Electronic device has substrate having at least one pad, electronic component having bump connected with pad of substrate electrically and mounting on substrate by flip chip bonding, conductive resin electrically connecting pad with bump, and insulation sheet disposed between substrate and electronic component. Substrate has recess on surface opposite to electronic component. Pad is formed on recess bottom. Conductive resin is provided on pad and in recess. Sheet has through hole corresponding to each bump. Opening area of through hole is smaller than that of recess. Bump is inserted into through hole, in contact with inner wall of through hole, electrically connected with pad via conductive resin, without direct contact with pad.

### REFERENCE TO RELATED APPLICATION

This application is based upon and claims the benefit of the priority of Japanese patent application No. 2007-275318, filed on Oct. 23, 2007, the disclosure of which is incorporated herein in its entirety by reference thereto.

### TECHNICAL FIELD

This invention relates to an electronic device mounting a electronic component, and a manufacturing method thereof. The invention relates to a semiconductor device mounting a semiconductor component as the electronic component by flip chip bonding and, a method of manufacturing the semiconductor device, for example.

### BACKGROUND

In recent years, for an electric bonding between an electronic component such as a semiconductor component and a substrate, lead-free solder is used mainly. Because of the high melting point of the lead-free solder, a solder-bonding process at high temperature is necessary. At the time of the mounting, therefore, it is necessary to pay attention to heat load on the substrate and mounted component. Because of the high elasticity of the lead-free solder, stress is also applied to the periphery of the bonding region. Therefore, it sometimes affects reliance on the connection at a stress-weak part such as a low-k film used in LSI. On the other hand, since connecting at a lower temperature is possible as compared with the solder, the conductive resin (conductive adhesive) can decrease the heat load. Also, there is an advantage that the stress on the connecting region decreases highly because of the lower elasticity of the conductive resin than the elasticity of the solder. The flip chip mounting using the conductive resin is disclosed in Patent Documents 1-3, for example.

In a flip chip bonding structure disclosed in Patent Document 1, a run-out part (a concave part, groove, resin-made electrode, for example) to guide extra bonding metal when a component is mounted is provided at an electrode on a substrate side in order to prevent generation of a short circuit between bumps when the bump is squashed.

In a method of mounting an electronic component, disclosed in Patent Document 2, a bump formed in the electronic component is fixed to a concave vessel, for putting the bump in, with a conductive bonding material in order to connect the electronic component with a print circuit board properly without adjusting the height of the bump even if the height of the bump formed in the electronic component and print circuit board is uneven.

In a semiconductor device disclosed in Patent document 3, a concave electrode made of metal is provided at a position opposite to an electrode pad of a semiconductor element in a semiconductor carrier substrate in order to prevent a short circuit between adjacent electrode terminals by solder or conductive adhesive at the time of a flip mounting and occurrence of Ag migration. An insulating sealing resin or a sheet sealer is applied at a region other than a plurality of the concave electrodes in order to supply the solder or conductive resin in the concave cavity of the concave electrode at once.

### [Patent Document 1]

JP Patent Kokai Publication No. JP-P2001-53432A

### [Patent Document 2]

JP Patent Kokai Publication No. JP-H08-222599A

### [Patent Document 3]

JP Patent Kokai Publication No. JP-P2000-208675A

### SUMMARY OF THE DISCLOSURE

The entire disclosures of Patent Documents 1 to 3 are incorporated herein by reference thereto.

The conductive resin (conductive adhesive) which is a mixture of metal particles and resin is difficult to form a desired shape at the time of the flip chip mounting. If a pad is formed on a flat surface of a substrate, there is a risk of a short circuit between adjacent pads because the conductive resin spreads around the pad when an electronic component is connected with the substrate electrically.

In the flip chip bonding structure disclosed in Patent Document 1, the run-out part (the concave part, groove, resin-made electrode) is formed at the electrode on the substrate side to prevent generation of a short circuit between adjacent pads. However, if the bump is in contact with the electrode on the substrate side directly, stress (resulting from a bend caused by heat at the time of bonding or action, especially) is applied on the bump by the contact between the solids. Therefore, there is a risk of damage of the electrical connection part.

The concave vessel disclosed in Patent Document 2 is a countermeasure against the unevenness of the height of the bumps. There is a risk that the conductive resin overflows from the concave part at the time of hardening because the opening of the concave part is opened. This leaves the risk of the short circuit between adjacent bumps. The stress is also applied on the bump by the contact between the solids (solid-solid contact) because the bump is in contact with the substrate (print circuit board) physically.

In the method of manufacturing the semiconductor device disclosed in Patent Document 3, the sheet sealer for supplying the conductive adhesive at once does not exist above the concave part. Therefore, this sheet sealer can not decrease the stress applied to the bump because the bump receives the stress from the conductive adhesive etc. directly as a whole.

It is an object of the present invention to provide an electronic device in which reliance on electrical connection between a substrate and an electronic component is enhanced, and a method of manufacturing the electronic device.

According to a first aspect of the invention, there is provided an electronic device. The electronic device comprises a substrate having at least one pad, an electronic component having a bump electrically connected with the pad of the substrate, and mounted on the substrate by flip chip bonding. The electronic device further comprises a conductive resin electrically connecting the pad with the bump, and an insulation sheet disposed between the substrate and the electronic component. The substrate has a recess, corresponding to the pad, on a surface (at a position) opposite to the electronic component. The pad is formed at least on the bottom of the recess. The conductive resin fills the recess above the pad. The sheet has a through hole corresponding to the bump, the opening area of the through hole smaller than the opening area of the recess. The bump is inserted into the through hole, being in contact with the inner wall of the through hole, so as to be electrically connected with the pad through the conductive resin without direct contact with the pad.

According to a preferred exemplar of the first aspect, the opening area of the through hole before the flip chip mounting is smaller than the opening area of the recess.

According to a preferred exemplar of the first aspect, the sheet comprises an elastic material.

According to a preferred exemplar of the first aspect, the width of the through hole before the flip chip mounting is smaller than the width of the widest part of the bump.

According to a second aspect of the present invention, there is provided a method of manufacturing an electronic device, which comprises an electronic component mounted on a substrate by flip chip bonding. The method comprises forming at least one recess in the substrate, forming a first pad on a bottom of at least one recess, providing a conductive resin on the first pad in the recess and forming at least one second pad in the electronic component and forming a bump on the second pad. The method further comprises: putting an insulation sheet on the substrate, the insulation sheet having at least one through hole, the through hole disposed over the recess; mounting the electronic component on the substrate, so as to sandwich the sheet between the sheet and the electronic component, the bump being inserted into the through hole and the recess. Then the conductive resin is cured to be hardened. The sheet has a thickness to prevent the bump from contacting with the first pad. The opening area of the through hole is smaller than the opening area of the recess.

According to a preferred exemplarity of the second aspect, the sheet may comprise an elastic material. The width of the through hole is smaller than the width of the widest part of the bump. Preferably, the curing may comprise heating for hardening.

The meritorious effects of the present invention are summarized as follows.

According to present invention, even if the conductive resin is used in the flip chip mounting of the electronic component with the substrate, a short circuit between adjacent bumps can be prevented because the flow of the conductive resin at the time of the flip chip mounting is restrained by the recess and the sheet.

According to the present invention, the sheet can prevent the direct contact between the bump of the electronic component and the pad of the substrate and reduce the stress exertable on the bump from the conductive resin and other elements. Therefore, the damage of the bump can be prevented to enhance the reliance on the connection.

### BRIEF DESCRIPTION OF THE DRAWINGS

FIG. 1 is a schematic and cross-sectional view illustrating an electronic device according to an exemplary embodiment of the present invention.

FIG. 2 is a schematic and cross-sectional view along a II-II line in FIG. 1.

FIG. 3 is a schematic and cross-sectional view enlarging an electrical connection part between an electronic component and a substrate in FIG. 1.

FIG. 4 is a schematic top plan view of a sheet used in the present exemplary embodiment.

FIGS. 5A to 5E show a schematic process to explain a method of manufacturing an electronic device according to an exemplary embodiment of the present invention.

### PREFERRED MODES OF THE INVENTION

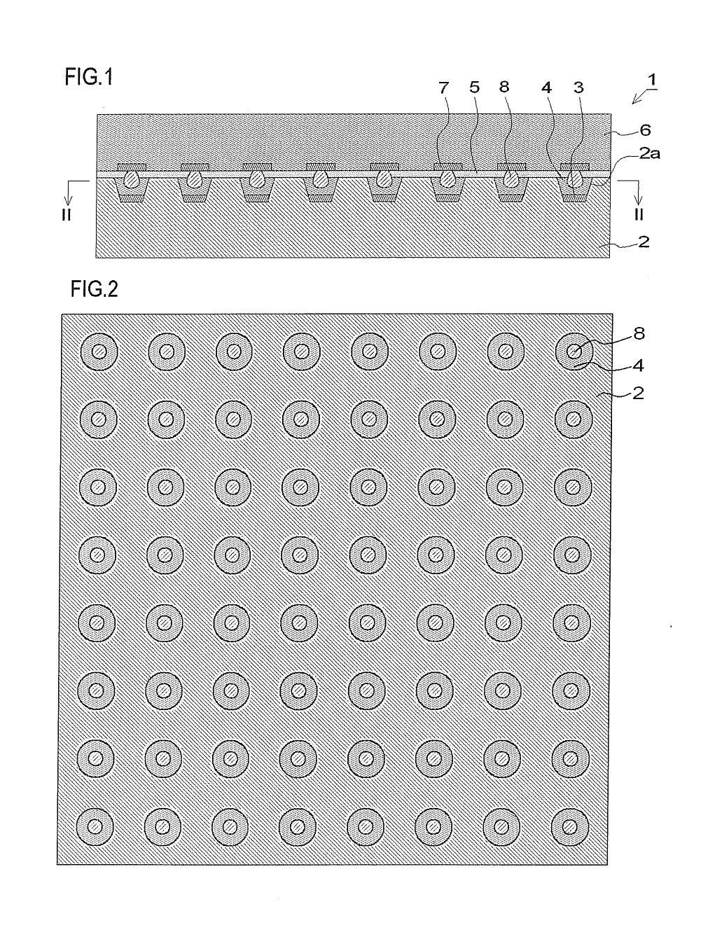

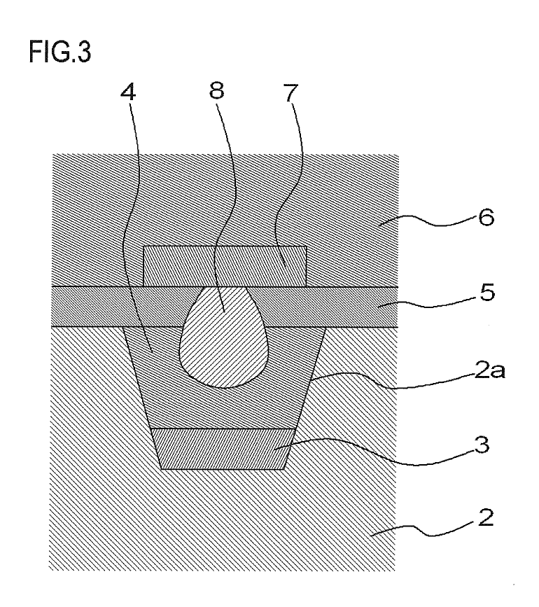

An electronic device will be explained by giving an example of a semiconductor device. FIG. 1 shows a schematic and cross-sectional view of the electronic device of an exemplary embodiment of the semiconductor device. FIG. 2 shows a schematic and cross-sectional view along a II-II line in FIG. 1. FIG. 3 shows a schematic and cross-sectional view enlarging an electrical connection part between an electronic component and a substrate. The electronic device 1 is a semiconductor device in which a semiconductor component 6 as the electronic component is mounted on a substrate 2 by flip chip bonding. In the substrate 2, recesses (or reentrants) 2a are formed on a surface opposite to the semiconductor component 6. At least one first pad (electrode) 3 for being electrically connected with the semiconductor component 6 is formed on the bottom (surface) of the recess 2a. A bump 8 formed on a second pad 7 of the semiconductor component 6 is connected with the first pad 3 of the substrate 2 via conductive resin (conductive adhesive) 4 provided on the first pad 3 and in the recess 2a. The bump 8 is not in direct contact with the first pad 3.

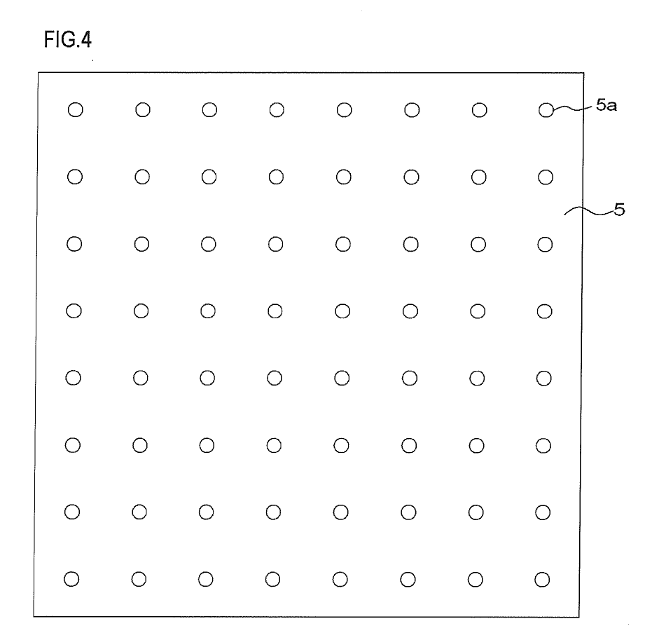

The semiconductor device 1 comprises a sheet 5 between the substrate 2 and the semiconductor component 6 which are connected by the flip chip bonding. FIG. 4 shows a schematic top plan view of the sheet. The sheet 5 is formed of an insulation material. The sheet 5 is preferably an elastic (flexible) material and a material of a rubber type, for example.

The sheet 5 has through holes 5a at the positions corresponding to the bumps 8 and recesses 2a. The bump 8 is in contact with the conductive resin 4 through the through hole 5a. The opening area of the through hole 5a is smaller than the opening area of the recess 2a. The opening area of the through hole 5a before the flip chip mounting (before insertion of the bump 8 into the through hole 5a) is smaller than the opening area of the recess 2a, preferably. Not only a region other than the recess 2a of the substrate 2 but also a region over the recess 2a other than the bump 8 are covered with the sheet 5. Therefore, the stress applied on the bump 8 from the conductive resin 4 and other elements can be reduced.

It is preferred that the width (diameter) or opening area of the through hole 5a of the sheet 5 before the mounting is designed so that the bump 8 is in contact with the inner wall of the through hole 5a after the insertion. This can seal (protect) the bump 8 and the connecting part between the bump 8 and the second pad 7 by the sheet 5 in which the bump 8 is in contact with the inner wall of the through hole 5a. In order to maintain the contact of the bump 8 with the inner wall of the through hole 5a, it is preferred that the width (diameter) or opening area of the through hole 5a of the sheet 5 before the mounting is generally similar to the width (diameter) of the widest part of the bump 8, or of the part having the largest cross section area in the cross section area of the bump 8 parallel to the surface of the semiconductor component 6, and further preferred that the width (diameter) or opening area of the through hole 5a is smaller than the part of the bump 8. Namely, it is preferred that the width (diameter) or opening area of the through hole 5a is designed so as to make it possible to insert the bump 8 into the through hole 5a owing to the elasticity of the sheet 5. The through hole 5a may have any form provided that the bump 8 can be inserted into the through hole 5a, and may have the (circular) openings as illustrated in FIG. 4 or a slit or notch into which the bump 8 can be inserted, for example.

It is preferred that the thickness of the sheet 5 is designed so that the bump 8 is not in direct contact with the first pad 3. Namely, the sheet 5 can also function as a spacer to adjust the distance between the bump 8 and the first pad 3.

According to the electronic device of the present invention, the reliance on the connection between the electronic component and the substrate can be enhanced because the stress applicable on the bump decreases.

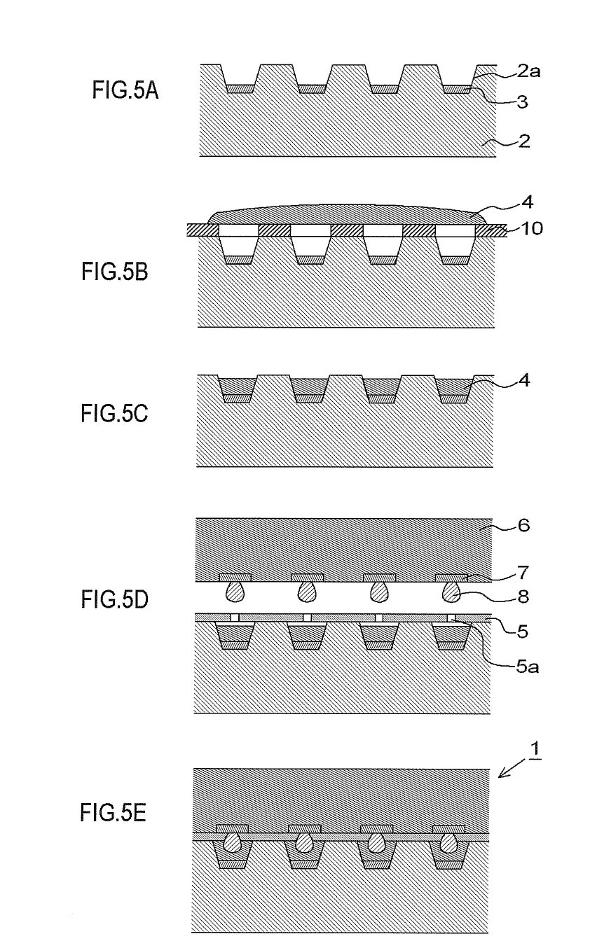

Next, a method of manufacturing the electronic device of the present invention will be explained by giving an example of a method of manufacturing the semiconductor device 1. FIG. 5 shows a schematic process of the method of manufacturing the electronic device of the present invention.

In a substrate 2, recesses 2a are formed at the positions at which first pads 3 are formed. The first pad 3 is formed on the bottom (surface) of a recess 2a (FIG. 5A). Next, the recess(es) 2a are filled with a conductive resin 4. The conductive resin 4 is provided in the recess(es) 2a using a (metal) mask 10, for example (FIGS. 5B, 5C). FIG. 5B illustrates a method in which the conductive resin 4 is printed on the first pads 3 using the mask 10. Next, a semiconductor component 6 having bumps 8 on second pads 7 and an insulation sheet 5 having through holes 5a to insert the bump 8 are prepared. The sheet 5 is put on the substrate 2 so as to match the position of the recess 2a with the position of the through hole 5a (FIG. 5D). Next, the semiconductor component 6 is mounted on the substrate 2 so that the sheet 5 is sandwiched between the substrate 2 and the semiconductor component 6 and that the bump 8 is inserted into the through hole 5a of the sheet 5 and the recess 2a. The bump 8 is electrically connected with the first pad 3 via the conductive resin 4 without direct contact due to the thickness of the sheet 5. Next, the conductive resin 4 is cured, e.g., by heating at a suitable temperature to be hardened when a thermally curable resin is used, and mounting the semiconductor 6 on the substrate is completed. Each element is designed so as to have the relationship as described above about the semiconductor device 1.

According to the manufacturing method of the present invention, the sheet can seal the conductive resin in the recess to suppress the generation of the short circuit between adjacent pads caused by the flow of the conductive resin. The sheet can also reduce the stress applicable onto the bump to enhance the reliance of the connection between the substrate and the electronic component. The sheet can further function as a spacer between the substrate and the electronic component in order to prevent the direct contact of the bump with the first pad.

Although the electronic device and manufacturing method thereof of the prevent invention are explained based on the above exemplar embodiments, the electronic device and manufacturing method thereof may include any modification, change and improvement to the exemplar embodiments within the claimed scope of the present invention and based on the technical idea of the present invention without being limited to those exemplar embodiments. Within the scope of the present invention, various combinations, displacements and selections of disclosed elements are available.

A further problem, object and examples of the present invention will become clear from the entire disclosure of the present invention including the drawings and claims.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. An electronic device comprising:
a substrate having at least one pad,
an electronic component having a bump electrically connected with said pad of said substrate and mounted on the substrate by a flip chip bonding,
a conductive resin electrically connecting said pad with said bump, and
an insulation sheet disposed between said substrate and the electronic component; wherein
said substrate has a recess, corresponding to said pad, on a surface opposite to said electronic component;
said pad is formed at least on the bottom of said recess;
said conductive resin fills said recess above said pad;
said sheet has a through hole corresponding to said bump, said through hole having an opening area smaller than that of said recess; and
said bump is inserted into said through hole, being in contact with an inner wall of said through hole, so as to be electrically connected with said pad through said conductive resin without direct contact with said pad.

2. The electronic device according to claim 1, wherein
the opening area of said through hole before the flip chip mounting is smaller than that of said recess.

3. The electronic device according to claim 1, wherein
said sheet comprises an elastic material.

4. The electronic device according to claim 3, wherein
said through hole has a width before the flip chip mounting smaller than that of the widest part of said bump.

5. A method of manufacturing an electronic device, said electronic device comprising an electronic component mounted on a substrate by flip chip bonding, the method comprising:
forming at least one recess in said substrate;
forming a first pad on a bottom of at least one recess;
providing a conductive resin on said first pad in said recess and;
forming at least one second pad in said electronic component and forming a bump on said second pad;
putting an insulation sheet on said substrate, the insulation sheet having at least one through hole, said through hole being disposed over said recess;
mounting said electronic component on said substrate so as to sandwich said sheet between said sheet and said electronic component, said bump being inserted into said through hole and said recess; and
curing said conductive resin; wherein
said sheet has a thickness to prevent said bump from contacting with said first pad; and
said through hole has an opening area smaller than that of said recess.

6. The method according to claim 5, wherein
said sheet comprises an elastic material; and
said through hole has a width smaller than that of the widest part of said bump.

7. The method according to claim 5, wherein
said curing comprises heating for hardening.
